(19) United States
(12) Patent Application Publication
(10) Pub. No.: US 2026/0304783 A1
(43) Pub. Date: Oct. 1, 2026

(54) MAGNETORESISTANCE EFFECT ELEMENT AND MAGNETIC MEMORY

(71) Applicant: TDK Corporation, Tokyo (JP)

(72) Inventor: Eiji KOMURA, Tokyo (JP)

(73) Assignee: TDK Corporation, Tokyo (JP)

(21) Appl. No.: 19/091,883

(22) Filed: Mar. 27, 2025

(51) Int. Cl. H10B 61/00; H10N 50/01; H10N 50/10

(52) U.S. Cl. CPC H10B 61/20; H10N 50/01; H10N 50/10

(57) ABSTRACT

This magnetoresistance effect element has a laminate, a first via wiring, and a second via wiring. The laminate has a spin-orbit torque wiring, a first ferromagnetic layer, a nonmagnetic layer, and a second ferromagnetic layer. The first via wiring is connected to the spin-orbit torque wiring. The second via wiring is connected to the spin-orbit torque wiring at a position different from a position of the first via wiring. The spin-orbit torque wiring is curved in a lamination direction with respect to a reference surface orthogonal to the lamination direction. A first connection surface in contact with the spin-orbit torque wiring of the first via wiring and a second connection surface in contact with the spin-orbit torque wiring of the second via wiring are curved along the spin-orbit torque wiring.

### TECHNICAL FIELD

The present disclosure relates to a magnetoresistance effect element and a magnetic memory.

### BACKGROUND ART

Giant magnetoresistance (GMR) elements constituted of a multilayer film having ferromagnetic layers and a nonmagnetic layer, and tunnel magnetoresistance (TMR) elements using an insulating layer (a tunnel barrier layer, a barrier layer) as a nonmagnetic layer are known as magnetoresistance effect elements. Magnetoresistance effect elements can be applied to magnetic sensors, high-frequency components, magnetic heads, and magnetic random access memories (MRAM).

An MRAM is a storage element in which a magnetoresistance effect element is integrated. An MRAM allows reading and writing of data utilizing characteristics of magnetoresistance effect elements whose resistance varies if magnetization directions of two ferromagnetic layers sandwiching a nonmagnetic layer therebetween in a magnetoresistance effect element vary. For example, the magnetization directions of ferromagnetic layers are controlled utilizing a magnetic field generated by a current. In addition, for example, the magnetization directions of ferromagnetic layers are controlled utilizing a spin transfer torque (STT) generated when a current flows in a lamination direction of a magnetoresistance effect element.

When the magnetization directions of ferromagnetic layers are rewritten utilizing an STT, a current flows in the lamination direction of a magnetoresistance effect element. A writing current may cause deterioration in characteristics of the magnetoresistance effect element.

In recent years, attention has been focused on methods requiring no current to flow in the lamination direction of a magnetoresistance effect element at the time of writing (for example, Patent Document 1). One of the methods is a writing method utilizing a spin-orbit torque (SOT). An SOT is induced due to a spin current generated by a spin-orbit interaction or a Rashba effect in an interface between different kinds of materials. A current for inducing an SOT into a magnetoresistance effect element flows in a direction intersecting the lamination direction of the magnetoresistance effect element. That is, in magnetization rotation using an SOT, there is no need for a current to flow in the lamination direction of the magnetoresistance effect element, and thus an extended lifespan of the magnetoresistance effect element is expected. Patent Document 1 discloses that a voltage effect when a voltage is applied to a nonmagnetic layer can be enhanced by causing the nonmagnetic layer to curve.

### Citation List

### Patent Document

Patent Document 1: Japanese Patent No. 6291608

### SUMMARY OF INVENTION

### Technical Problem

A spin-orbit torque is induced when a current flows in a spin-orbit torque wiring and spins are injected into a ferromagnetic layer from the spin-orbit torque wiring. Heavy metals are often used for spin-orbit torque wirings. Heavy metals have a high resistance and become a heat source when a current flows therethrough. In order to enhance stability of data in magnetoresistance effect elements, it is required to efficiently release heat. On the other hand, in order to enhance the efficiency of writing data in magnetoresistance effect elements, it is required to increase the amount of spins injected into a ferromagnetic layer from a spin-orbit torque wiring. If the amount of spins injected into a ferromagnetic layer from a spin-orbit torque wiring is increased, the amount of heat generated in the spin-orbit torque wiring increases. There is a demand for both ease of writing data in magnetoresistance effect elements and stability of data in magnetoresistance effect elements.

The present disclosure has been made in consideration of the foregoing circumstances, and an object thereof is to provide a magnetoresistance effect element and a magnetic memory having excellent heat dissipation properties and high spin injection efficiency.

### Solution to Problem

In order to resolve the foregoing problems, the present disclosure provides the following means.

A magnetoresistance effect element according to a first aspect has a laminate, a first via wiring, and a second via wiring. The laminate has a spin-orbit torque wiring, a first ferromagnetic layer, a nonmagnetic layer, and a second ferromagnetic layer. The first ferromagnetic layer is located between the spin-orbit torque wiring and the nonmagnetic layer in a lamination direction of the laminate. The nonmagnetic layer is located between the first ferromagnetic layer and the second ferromagnetic layer in the lamination direction of the laminate. The first via wiring is connected to the spin-orbit torque wiring. The second via wiring is connected to the spin-orbit torque wiring at a position different from a position of the first via wiring. The spin-orbit torque wiring is curved in the lamination direction with respect to a reference surface orthogonal to the lamination direction. A first connection surface in contact with the spin-orbit torque wiring of the first via wiring and a second connection surface in contact with the spin-orbit torque wiring of the second via wiring are curved along the spin-orbit torque wiring.

### Advantageous Effects of Invention

The magnetoresistance effect element and the magnetic memory according to the present disclosure have excellent heat dissipation properties and high spin injection efficiency.

### BRIEF DESCRIPTION OF DRAWINGS

FIG. 1 A schematic circuit diagram of a magnetic memory according to a first embodiment.

FIG. 2 A cross-sectional view of a characteristic portion of the magnetic memory according to the first embodiment.

FIG. 3 A cross-sectional view of a magnetoresistance effect element according to the first embodiment.

FIG. 4 A plan view of the magnetoresistance effect element according to the first embodiment.

FIG. 5 An explanatory view of a method for manufacturing the magnetoresistance effect element according to the first embodiment.

FIG. 6 A cross-sectional view of a magnetoresistance effect element according to a second embodiment.

FIG. 7 A cross-sectional view of a magnetoresistance effect element according to a third embodiment.

### DESCRIPTION OF EMBODIMENTS

Hereinafter, the present embodiment will be described in detail suitably with reference to the drawings. In the drawings used in the following description, in order to make characteristics easy to understand, characteristic portions may be shown in an enlarged manner for the sake of convenience, and dimensional ratios or the like of each constituent element may differ from actual values thereof. Materials, dimensions, and the like shown in the following description are merely exemplary examples. The present disclosure is not limited thereto and can be suitably changed and performed within a range in which the effects of the present disclosure are exhibited.

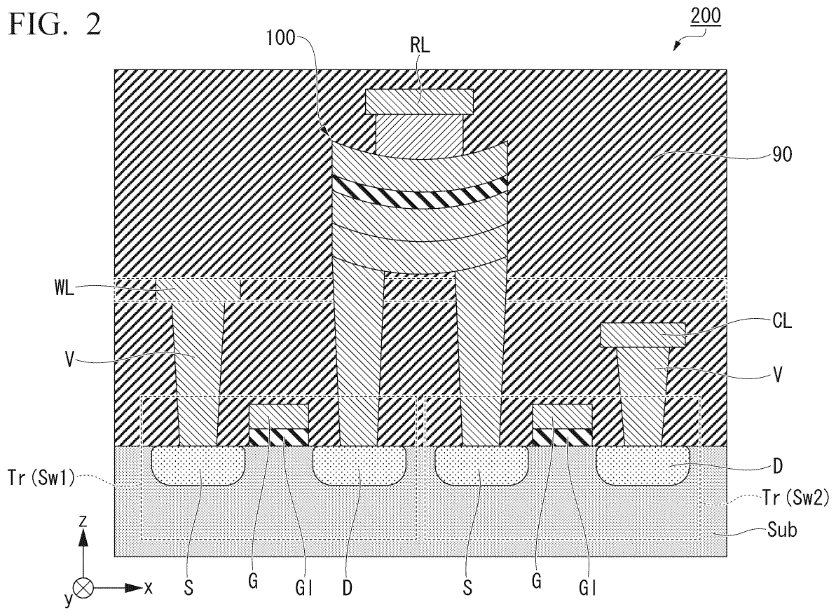

First, directions will be defined. One direction on a surface of a substrate Sub, which will be described below (refer to FIG. 2), will be regarded as an X direction, and a direction orthogonal to the X direction will be regarded as a Y direction. For example, the X direction is a direction along a line connecting a first via wiring and a second via wiring at the shortest distance. A Z direction is a direction orthogonal to the X direction and the Y direction. The Z direction is an example of a lamination direction in which layers are laminated. Hereinafter, a direction from the substrate Sub toward a magnetoresistance effect element will be regarded as the positive Z direction and may be expressed as “upward”. In addition, a direction opposite to the positive Z direction (negative Z direction) may be expressed as “downward”. The upward-downward direction does not necessarily coincide with a direction in which gravity is applied.

In this specification, for example, the expression “extending in the X direction” means that the dimension in the X direction is larger than the smallest dimension of the dimensions in the X direction, the Y direction, and the Z direction. The same applies to the cases of extending in other directions. In addition, in this specification, the term “connection” is not limited to a case of being physically connected. For example, the term “connection” is not limited to a case in which two layers are physically in contact with each other, and it also includes a case in which two layers are connected to each other with another layer sandwiched therebetween. In addition, in this specification, the term “connection” also includes electrical connection.

### First Embodiment

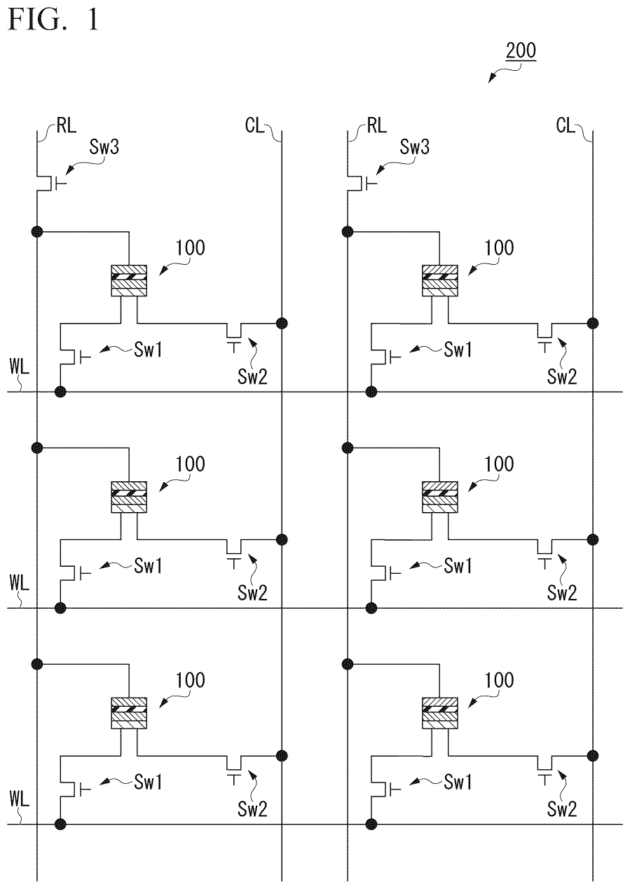

FIG. 1 is a view of a constitution of a magnetic memory 200 according to a first embodiment. The magnetic memory 200 includes a plurality of magnetoresistance effect elements 100, a plurality of writing wirings WL, a plurality of common wirings CL, a plurality of reading wirings RL, a plurality of first switching elements Sw1, a plurality of second switching elements Sw2, and a plurality of third switching elements Sw3. For example, in the magnetic memory 200, the magnetoresistance effect elements 100 are arrayed in a matrix shape.

Each of the writing wirings WL electrically connects a power source to one or more magnetoresistance effect elements 100. Each of the common wirings CL is a wiring used at times of both writing and reading data. Each of the common wirings CL electrically connects a reference potential to one or more magnetoresistance effect elements 100. For example, the reference potential is a ground potential. The common wiring CL may be provided in each of the plurality of magnetoresistance effect elements 100 or may be provided across the plurality of magnetoresistance effect elements 100. Each of the reading wirings RL electrically connects the power source to one or more magnetoresistance effect elements 100. The power source is connected to the magnetic memory 200 when in use.

Each of the magnetoresistance effect elements 100 is connected to the first switching element Sw1, the second switching element Sw2, and the third switching element Sw3. The first switching element Sw1 is connected between the magnetoresistance effect element 100 and the writing wiring WL. The second switching element Sw2 is connected between the magnetoresistance effect element 100 and the common wiring CL. The third switching element Sw3 is connected to the reading wiring RL across the plurality of magnetoresistance effect elements 100.

If a predetermined first switching element Sw1 and a predetermined second switching element Sw2 are turned on, a writing current flows between the writing wiring WL and the common wiring CL connected to a predetermined magnetoresistance effect element 100. Due to a writing current flowing therethrough, data is written in the predetermined magnetoresistance effect element 100. If a predetermined second switching element Sw2 and a predetermined third switching element Sw3 are turned on, a reading current flows between the common wiring CL and the reading wiring RL connected to a predetermined magnetoresistance effect element 100. Due to a reading current flowing therethrough, data is read from the predetermined magnetoresistance effect element 100.

The first switching element Sw1, the second switching element Sw2, and the third switching element Sw3 are elements for controlling a flow of a current. For example, the first switching element Sw1, the second switching element Sw2, and the third switching element Sw3 are transistors. For example, the first switching element Sw1, the second switching element Sw2, and the third switching element Sw3 may be elements such as ovonic threshold switches (OTS) utilizing phase change in a crystal layer, elements such as metal insulator transfer (MIT) switches utilizing variation in a band structure, elements such as Zener diodes and avalanche diodes utilizing a breakdown voltage, or elements whose conductivity varies in accordance with variation in atom positions.

The third switching element Sw3 of the magnetic memory 200 shown in FIG. 1 is shared by the magnetoresistance effect element 100 connected to the same reading wiring RL. The third switching element Sw3 may be provided in each of the magnetoresistance effect elements 100. In addition, the third switching element Sw3 may be provided in each of the magnetoresistance effect elements 100, and the first switching element Sw1 or the second switching element Sw2 may be shared by the magnetoresistance effect element 100 connected to the same wiring.

FIG. 2 is a cross-sectional view of a characteristic portion of the magnetic memory 200 according to the first embodiment. FIG. 2 is a cross section cut along an XZ plane passing through the center of the magnetoresistance effect element 100 in the Y direction.

The first switching element Sw1 and the second switching element Sw2 shown in FIG. 2 are transistors Tr. The third switching element Sw3 is electrically connected to the reading wiring RL and is located, for example, at a different position in the Y direction in FIG. 2. For example, the transistors Tr are field effect transistors each having a gate electrode G, a gate insulating film GI, a source S, and a drain D. The source S and the drain D are prearranged depending on a flowing direction of a current, and the positional relationship between the source S and the drain D may be reversed. For example, the substrate Sub is a semiconductor substrate.

The transistor Tr and the writing wiring WL or the common wiring CL are connected via a via wiring V. For example, the via wiring V extends in the Z direction. The reading wiring RL is connected to the magnetoresistance effect element 100. The via wiring V contains a conductive material.

Areas around the magnetoresistance effect element 100 and the transistors Tr are covered by an insulating layer 90. The insulating layer 90 is an insulating layer providing insulation between wirings of a multilayer wiring or between elements. For example, the insulating layer 90 is made of silicon oxide (SiOₓ), silicon nitride (SiNₓ), silicon carbide (SiC), chromium nitride (CrN), silicon carbonitride (SiCN), silicon oxynitride (SiON), aluminum oxide (Al₂O₃), zirconium oxide (ZrOₓ), magnesium oxide (MgO), aluminum nitride (AlN), or the like.

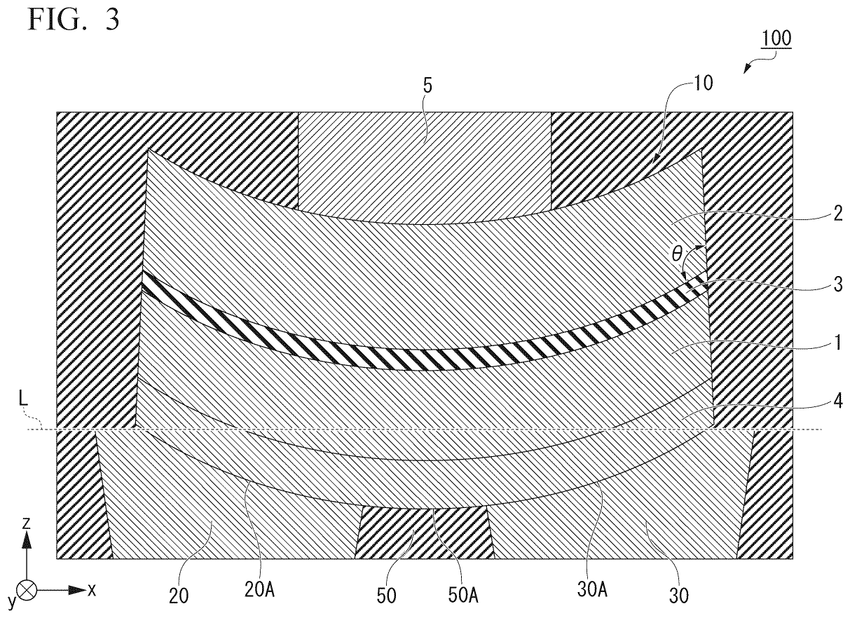

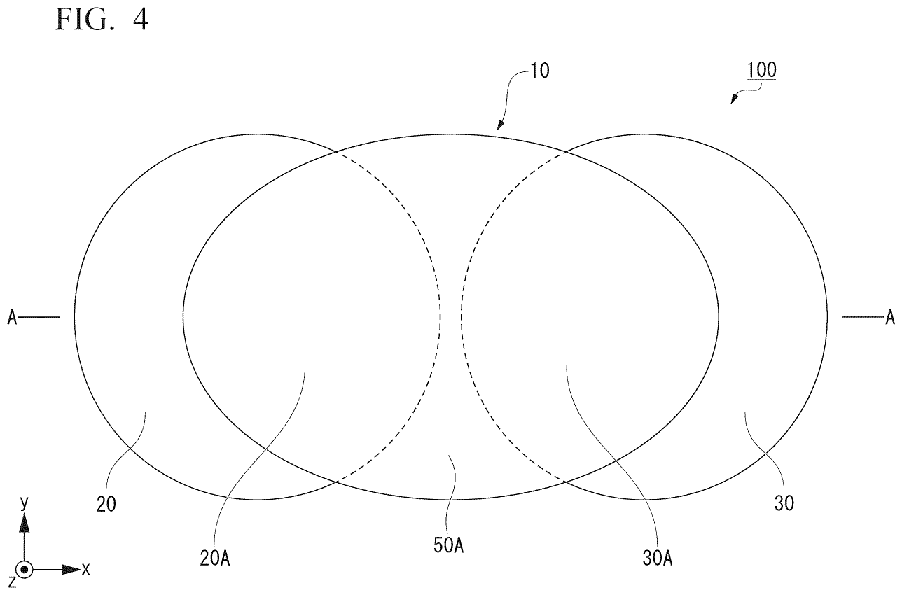

FIG. 3 is a cross-sectional view of the magnetoresistance effect element 100 according to the first embodiment. FIG. 4 is a plan view of the magnetoresistance effect element 100 according to the first embodiment. FIG. 3 an XZ cross section cut along line A-A in FIG. 4. Line A-A a line along the line connecting a first via wiring 20 and a second via wiring 30 at the shortest distance. In FIG. 4, an electrode 5 and the insulating layer 90 are omitted.

For example, the magnetoresistance effect element 100 includes a laminate 10, the first via wiring 20, and the second via wiring 30. The magnetoresistance effect element 100 is a magnetic element utilizing a spin-orbit torque (SOT) and may be referred to as a spin-orbit torque-type magnetoresistance effect element, a spin injection-type magnetoresistance effect element, or a spin current magnetoresistance effect element.

The magnetoresistance effect element 100 is an element which records and saves data. The magnetoresistance effect element 100 records data using a resistance value of the laminate 10 in the Z direction. The resistance value of the laminate 10 in the Z direction varies when a writing current is applied along a spin-orbit torque wiring 4 and spins are injected into a first ferromagnetic layer 1 from the spin-orbit torque wiring 4. The resistance value of the laminate 10 in the Z direction can be read by applying a reading current in the Z direction of the laminate 10.

The laminate 10 has the first ferromagnetic layer 1, a second ferromagnetic layer 2, a nonmagnetic layer 3, and the spin-orbit torque wiring 4. The laminate 10 may have the electrode 5 connecting the reading wiring RL and the second ferromagnetic layer 2. For example, in the laminate 10, the spin-orbit torque wiring 4, the first ferromagnetic layer 1, the nonmagnetic layer 3, and the second ferromagnetic layer 2 are laminated in this order from the side closer to the substrate Sub.

The resistance value of the laminate 10 in the Z direction varies when spins are injected into the first ferromagnetic layer 1 from the spin-orbit torque wiring 4. The resistance value of the laminate 10 in the Z direction varies when the relative angle of magnetization between the first ferromagnetic layer 1 and the second ferromagnetic layer 2 sandwiching the nonmagnetic layer 3 therebetween varies.

In the laminate 10, for example, the shape of the laminate 10 in a planar view in the z direction is a circular shape, an oval shape, or a quadrangular shape. For example, side surfaces of the laminate 10 are continuous in the Z direction and may be inclined with respect to the Z direction. The side surfaces being continuous in the Z direction means that there is no significant step in an interface between layers, and side surfaces of the layers form a single surface.

The spin-orbit torque wiring 4 generates a spin current due to a spin Hall effect occurring when a current flows and injects spins into the first ferromagnetic layer 1. For example, the spin-orbit torque wiring 4 applies a spin-orbit torque (SOT) to the magnetization of the first ferromagnetic layer 1 by an amount with which the magnetization of the first ferromagnetic layer 1 can be reversed.

The spin Hall effect is a phenomenon in which a spin current is induced in a direction orthogonal to the flowing direction of a current based on a spin-orbit interaction when a current flows. The spin Hall effect is in common with a normal Hall effect in that kinetic (moving) charge (electrons) can bend the kinetic (moving) direction. The normal Hall effect causes the kinetic direction of kinetic charged particles in a magnetic field to bend by means of a Lorentz force. In contrast, the spin Hall effect causes the moving direction of spins to bend simply by means of moving electrons (flowing currents) even if there is no magnetic field.

For example, if a current flows in the spin-orbit torque wiring 4, first spins polarized in one direction and second spins polarized in a direction opposite to that of the first spins individually bend due to the spin Hall effect in a direction orthogonal to the flowing direction of the current. For example, the first spins polarized in the negative Y direction bend in the positive Z direction from the X direction that is the traveling direction thereof, and the second spins polarized in the positive Y direction bend in the negative Z direction from the x direction that is the traveling direction thereof.

In a nonmagnetic body (a material that is not a ferromagnetic body), the number of electrons in the first spins and the number of electrons in the second spins generated due to the spin Hall effect are the same. That is, the number of electrons in the first spins toward the positive Z direction and the number of electrons in the second spins toward the negative Z direction are the same. The first spins and the second spins flow in directions in which an uneven distribution of the spins is eliminated. Since flows of charge are offset each other in movement of the first spins and the second spins in the Z direction, the current amount becomes zero. A spin current accompanying no current is particularly referred to as a pure spin current.

When a flow of electrons in the first spins is expressed as J_{↑}, a flow of electrons in the second spins is expressed as J_{↓}, and a spin current is expressed as J_{S}, these are defined as J_{S}=J_{↑}−J_{↓}. The spin current J_{S} is generated in the Z direction. The first spins are injected into the first ferromagnetic layer 1 from the spin-orbit torque wiring 4.

For example, the thickness of the spin-orbit torque wiring 4 is 2 nm or larger. For example, the thickness of the spin-orbit torque wiring 4 may be 20 nm or smaller.

The spin-orbit torque wiring 4 contains any of a metal, an alloy, an intermetallic compound, a metal boride, a metal carbide, a metal silicide, a metal phosphide, and a metal nitride having a function of generating a spin current.

For example, the spin-orbit torque wiring 4 contains any one selected from the group consisting of a heavy metal whose atomic number is 39 or larger, a metal oxide, a metal nitride, a metal oxynitride, and a topological insulator. In addition, the spin-orbit torque wiring 4 may contain a magnetic material.

For example, the spin-orbit torque wiring 4 contains a nonmagnetic heavy metal as a main component. A heavy metal means a metal having a specific gravity equal to or greater than that of yttrium (Y). For example, a nonmagnetic heavy metal is a nonmagnetic metal having d electrons or f electrons in its outermost shell and having a large atomic number (atomic number 39 or larger). In a nonmagnetic heavy metal, a spin-orbit interaction stronger than those in other metals occurs. A spin Hall effect occurs due to a spin-orbit interaction, and spins are likely to be unevenly distributed inside the spin-orbit torque wiring 4 so that the spin current J_{S} is likely to be generated.

The spin-orbit torque wiring 4 is curved in the Z direction with respect to a reference surface L. For example, the spin-orbit torque wiring 4 is curved in a downward convex manner with respect to the reference surface L. The center of the spin-orbit torque wiring 4 in the X direction is curved toward the substrate Sub side from both ends of the spin-orbit torque wiring 4 in the X direction. Since the spin-orbit torque wiring 4 is curved, the current path between the first via wiring 20 and the second via wiring 30 is lengthened so that the amount of spins injected into the first ferromagnetic layer 1 from the spin-orbit torque wiring 4 can be increased.

For example, the first ferromagnetic layer 1 comes into contact with the spin-orbit torque wiring 4 and is laminated on the spin-orbit torque wiring 4. The first ferromagnetic layer 1 is curved along the spin-orbit torque wiring 4.

The first ferromagnetic layer 1 is located between the first ferromagnetic layer 1 and the nonmagnetic layer 3 in the Z direction. The first ferromagnetic layer 1 is closer to the spin-orbit torque wiring 4 than the second ferromagnetic layer 2. Spins are injected into the first ferromagnetic layer 1 from the spin-orbit torque wiring 4. The magnetization of the first ferromagnetic layer 1 receives a spin-orbit torque (SOT) due to injected spins so that an orientation direction thereof varies. The first ferromagnetic layer 1 is sometimes referred to as a magnetization free layer.

The first ferromagnetic layer 1 contains a ferromagnetic body. For example, the ferromagnetic body is a metal selected from the group consisting of Cr, Mn, Co, Fe, and Ni; an alloy containing one or more kinds of these metals; an alloy containing at least one or more kinds of elements of these metals, B, C, and N; or the like. For example, the ferromagnetic body is an alloy of Co—Fe, Co—Fe—B, Ni—Fe, or Co—Ho; a Sm—Fe alloy; a Fe—Pt alloy; a Co—Pt alloy; or a CoCrPt alloy.

The first ferromagnetic layer 1 may contain a Heusler alloy. The Heusler alloy contains an intermetallic compound having a chemical composition of XYZ or X₂YZ. X represents a transition metal element or a noble metal element of the Co group, the Fe group, the Ni group, or the Cu group on the periodic table. Y represents a transition metal of the Mn group, the V group, the Cr group, or the Ti group, or a kind of an element represented by X. Z represents a typical element of Group III to Group V. For example, the Heusler alloy consists of Co₂FeSi, Co₂FeGe, Co₂FeGa, Co₂MnSi, Co₂Mn₁₋ₐFeₐAl_{b}Si_{1-b}, Co₂FeGe_{1-c}Ga_{c}, or the like. The Heusler alloy has a high spin polarization.

The nonmagnetic layer 3 is sandwiched between the first ferromagnetic layer 1 and the second ferromagnetic layer 2 in the Z direction. The nonmagnetic layer 3 is curved along the spin-orbit torque wiring 4.

The nonmagnetic layer 3 contains a nonmagnetic body. When the nonmagnetic layer 3 is an insulator (when it is a tunnel barrier layer), for example, Al₂O₃, SiO₂, MgO, MgAl₂O₄, or the like can be used as a material thereof. In addition to these, a material or the like in which a part of Al, Si, or Mg is replaced with Zn, Be, or the like can also be used for the nonmagnetic layer 3. Among these, MgO and MgAl₂O₄ are materials which can realize coherent tunneling. When the nonmagnetic layer 3 is made of a metal, Cu, Au, Ag, or the like can be used as a material thereof. Moreover, when the nonmagnetic layer 3 is constituted of a semiconductor, Si, Ge, CuInSe₂, CuGaSe₂, Cu(In, Ga)Se₂, or the like can be used as a material thereof.

The second ferromagnetic layer 2 is located at a position farther from the spin-orbit torque wiring 4 than the first ferromagnetic layer 1. The second ferromagnetic layer 2 is curved along the spin-orbit torque wiring 4. The orientation direction of the magnetization of the second ferromagnetic layer 2 is less likely to vary than that of the magnetization of the first ferromagnetic layer 1 when a predetermined external force is applied thereto. The second ferromagnetic layer 2 is referred to as a magnetization fixed layer or a magnetization reference layer.

The second ferromagnetic layer 2 contains a ferromagnetic body. A material similar to that of the first ferromagnetic layer 1 can be used for the second ferromagnetic layer 2.

An angle θ formed by the interface between the second ferromagnetic layer 2 and the nonmagnetic layer 3, and the side surface of the laminate 10 may be larger than 90°. The volume of the second ferromagnetic layer 2 increases as the angle θ increases. If the volume of the second ferromagnetic layer 2 is large, the magnetization stability of the second ferromagnetic layer 2 is enhanced so that a back-hopping phenomenon can be curbed. A back-hopping phenomenon is a phenomenon in which magnetization reverses.

The laminate 10 may have a layer other than the first ferromagnetic layer 1, the second ferromagnetic layer 2, the nonmagnetic layer 3, and the spin-orbit torque wiring. For example, the laminate 10 may have a cap layer on its top surface.

The first via wiring 20 is connected to the spin-orbit torque wiring 4 of the laminate 10. For example, the first via wiring 20 is connected to a first end of the spin-orbit torque wiring 4.

The first via wiring 20 is made of a conductive material. The first via wiring 20 has better conductivity than the spin-orbit torque wiring 4. For example, the conductivity of the element constituting the first via wiring 20 is higher than the conductivity of the element constituting the spin-orbit torque wiring 4. For example, the first via wiring 20 is made of Cu, Al, Ag, or the like.

A first connection surface 20A of the first via wiring 20 is curved along the spin-orbit torque wiring 4. The first connection surface 20A is a connection surface between the first via wiring 20 and the spin-orbit torque wiring 4. Since the first connection surface 20A is curved, the contact area between the spin-orbit torque wiring 4 and the first via wiring 20 increases so that heat generated in the spin-orbit torque wiring 4 can be efficiently released from the first via wiring 20.

The second via wiring 30 is connected to the spin-orbit torque wiring 4 of the laminate 10. The second via wiring 30 is connected to the spin-orbit torque wiring 4 at a position different from that of the first via wiring 20. For example, the first via wiring 20 is connected to a second end of the spin-orbit torque wiring 4.

The first via wiring 20 and the second via wiring 30 are closest to each other in the X direction. As the distance between the first via wiring 20 and the second via wiring 30 becomes shorter, heat generated in the spin-orbit torque wiring 4 can be more efficiently dissipated. For example, the shortest distance between the first via wiring 20 and the second via wiring 30 is 5 nm to 40 nm.

The second via wiring 30 is made of a conductive material. A material similar to that of the first via wiring 20 can be used for the second via wiring 30.

A second connection surface 30A of the second via wiring 30 is curved along the spin-orbit torque wiring 4. The second connection surface 30A is a connection surface between the second via wiring 30 and the spin-orbit torque wiring 4. Since the second connection surface 30A is curved, the contact area between the spin-orbit torque wiring 4 and the second via wiring 30 increases so that heat generated in the spin-orbit torque wiring 4 can be efficiently released from the second via wiring 30.

There is an insulating layer 50 between the first via wiring 20 and the second via wiring 30. The insulating layer 50 is a part of the insulating layer 90. A third connection surface 50A of the insulating layer 50 is curved along the spin-orbit torque wiring 4. The third connection surface 50A is a connection surface between the insulating layer 50 and the spin-orbit torque wiring 4.

As shown in FIG. 3, it is preferable that the sum of the curved surface length of the first connection surface 20A and the second connection surface 30A be longer than the curved surface length of the third connection surface 50A. As the curved surface length of the third connection surface 50A becomes shorter, heat generated in the spin-orbit torque wiring 4 can be more efficiently dissipated.

In addition, as shown in FIG. 4, it is preferable that the total area of the first connection surface 20A and the second connection surface 30A be larger than the area of the third connection surface 50A. As the total area of the first connection surface 20A and the second connection surface 30A becomes larger, heat generated in the spin-orbit torque wiring 4 can be more efficiently dissipated.

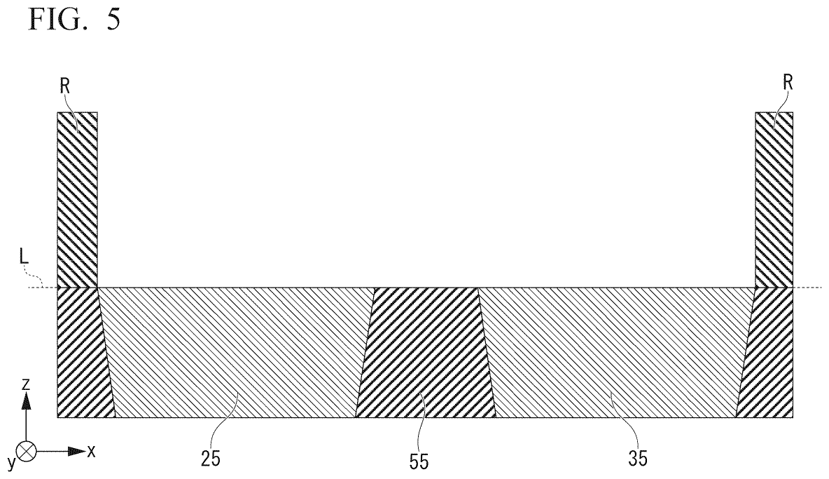

Next, a method for manufacturing the magnetoresistance effect element 100 will be described. FIG. 5 is an explanatory view of a method for manufacturing the magnetoresistance effect element 100 according to the first embodiment.

The magnetoresistance effect element 100 can be produced by laminating layers and processing layers repeatedly. The layers can be laminated using a sputtering method, a chemical vapor deposition (CVD) method, an electron beam evaporation method (EB evaporation method), an atom laser deposition (ALD) method, or the like. For example, the layers can be processed using photolithography or the like.

First, a part of the insulating layer 90 is formed such that the transistors Tr are covered. In addition, a first via wiring 25 and a second via wiring 35 are formed by forming opening portions in the insulating layer 90 and filling the insides of the opening portions with conductors. An insulating layer 55 is formed between the first via wiring 25 and the second via wiring 35.

The writing wirings WL and the common wirings CL can be formed by laminating the insulating layer 90 to a predetermined thickness, then forming grooves in the insulating layer 90, and filling the grooves with conductors.

Next, a resist R is formed so as to surround outward sides of the first via wiring 25 and the second via wiring 35. Further, upper surfaces of the first via wiring 25, the insulating layer 55, and the second via wiring 35 are etched by emitting an ion beam in an oblique direction toward the opening portion of the resist R. By etching these upper surfaces, the first via wiring 25 becomes the first via wiring 20, the insulating layer 55 becomes the insulating layer 50, and the second via wiring 35 becomes the second via wiring 30.

Next, after the resist is removed, the laminate 10 is formed. The spin-orbit torque wiring 4, the first ferromagnetic layer 1, the nonmagnetic layer 3, and the second ferromagnetic layer 2 are laminated in this order and are processed into desired shapes. The side surfaces of the laminate 10 become continuous by processing the spin-orbit torque wiring 4, the first ferromagnetic layer 1, the nonmagnetic layer 3, and the second ferromagnetic layer 2 together. Further, after the electrode 5 is formed, areas around the laminate 10 are covered with the insulating layer 90, thereby obtaining the magnetoresistance effect element 100 according to the first embodiment.

The magnetoresistance effect element 100 according to the first embodiment has excellent heat dissipation properties because the areas of the first connection surface 20A and the second connection surface 30A are larger than when the spin-orbit torque wiring 4 is flat. In addition, in the magnetoresistance effect element 100 according to the first embodiment, since the spin-orbit torque wiring 4 is curved, the current path between the first via wiring 20 and the second via wiring 30 can be lengthened so that the amount of spins injected into the first ferromagnetic layer 1 from the spin-orbit torque wiring 4 can be increased. When the distance between the first via wiring 20 and the second via wiring 30 is reduced, the current path between the first via wiring 20 and the second via wiring 30 is likely to be shortened. Since the spin-orbit torque wiring 4 is curved, heat dissipation properties of the magnetoresistance effect element 100 can be enhanced, while a current path having a sufficient length is secured.

The efficiency of writing data in the magnetoresistance effect element 100 is enhanced as the amount of spins with respect to the amount of writing current increases. In the magnetoresistance effect element 100 according to the first embodiment, since the contact area between the spin-orbit torque wiring 4 and the first ferromagnetic layer 1 is large, the amount of spins injected into the first ferromagnetic layer 1 from the spin-orbit torque wiring 4 is large and the writing efficiency is excellent.

In addition, as the spin-orbit torque wiring 4 generates heat, the magnetization stability of the first ferromagnetic layer 1 and the second ferromagnetic layer 2 declines so that stability of data in the magnetoresistance effect element 100 declines. In addition, if the spin-orbit torque wiring 4 excessively generates heat, the magnetoresistance effect element 100 itself may be damaged. The magnetoresistance effect element 100 according to the first embodiment has excellent heat dissipation properties, and therefore it can stably store data.

### Second Embodiment

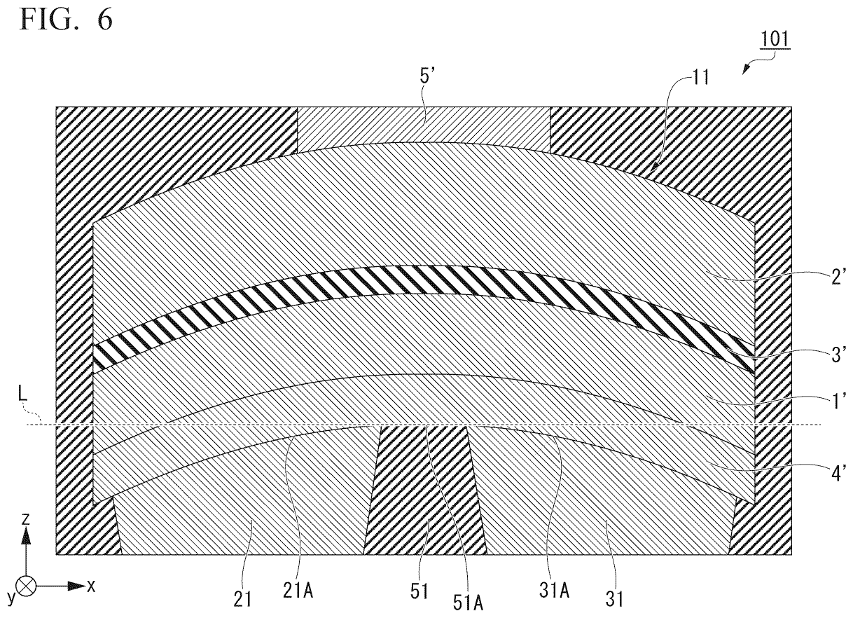

FIG. 6 is a cross-sectional view of a magnetoresistance effect element 101 according to a second embodiment. The magnetoresistance effect element 101 according to the second embodiment can be replaced by the magnetoresistance effect element 100 according to the first embodiment. In the magnetoresistance effect element 101 according to the second embodiment, a curve direction of a laminate 11 differs from the laminate 10 of the magnetoresistance effect element 100 according to the first embodiment.

The magnetoresistance effect element 101 has the laminate 11, a first via wiring 21, and a second via wiring 31.

The laminate 11 is similar to the laminate 10 except for the curve direction. The laminate 11 has a first ferromagnetic layer 1′, a second ferromagnetic layer 2′, a nonmagnetic layer 3′, and a spin-orbit torque wiring 4′. The first ferromagnetic layer 1′ corresponds to the first ferromagnetic layer 1 except for the curve direction. The second ferromagnetic layer 2′ corresponds to the second ferromagnetic layer 2 except for the curve direction. The nonmagnetic layer 3′ corresponds to the nonmagnetic layer 3 except for the curve direction. The spin-orbit torque wiring 4′ corresponds to the spin-orbit torque wiring 4 except for the curve direction.

For example, the spin-orbit torque wiring 4′ is curved in an upward convex manner with respect to the reference surface L. The center of the spin-orbit torque wiring 4′ in the X direction is curved in a direction in which it becomes farther from the substrate Sub side than both ends of the spin-orbit torque wiring 4 in the X direction. The first ferromagnetic layer 1′, the nonmagnetic layer 3′, and the second ferromagnetic layer 2′ are curved along the spin-orbit torque wiring 4′.

The first via wiring 21 corresponds to the first via wiring 20 except for the curve direction of a first connection surface 21A. The second via wiring 31 corresponds to the second via wiring 30 except for the curve direction of a second connection surface 31A. An insulating layer 51 corresponds to the insulating layer 50 except for the curve direction of a third connection surface 51A. It is preferable that the sum of the curved surface length of the first connection surface 21A and the second connection surface 31A be longer than the curved surface length of the third connection surface 51A, and it is preferable that the total area of the first connection surface 21A and the second connection surface 31A be larger than the area of the third connection surface 51A.

The magnetoresistance effect element 101 according to the second embodiment differs from the magnetoresistance effect element 100 simply in the curve direction of the layers and exhibits an effect similar to that of the magnetoresistance effect element 100.

### Third Embodiment

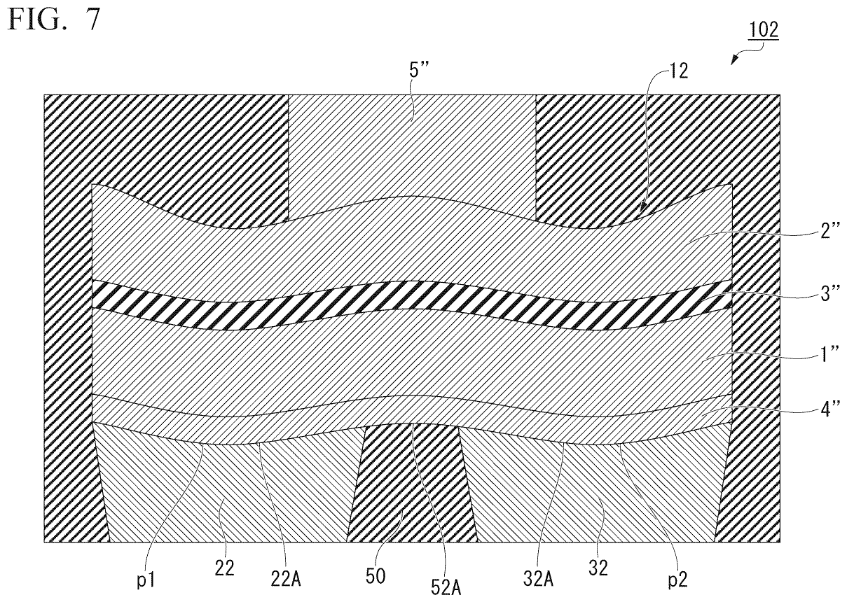

FIG. 7 is a cross-sectional view of a magnetoresistance effect element 102 according to a third embodiment. The magnetoresistance effect element 102 according to the third embodiment can be replaced by the magnetoresistance effect element 100 according to the first embodiment. In the magnetoresistance effect element 102 according to the third embodiment, the curve direction of a laminate 12 differs from the laminate 10 of the magnetoresistance effect element 100 according to the first embodiment.

The magnetoresistance effect element 102 has the laminate 12, a first via wiring 22, and a second via wiring 32.

The laminate 12 is similar to the laminate 10 except for the curve direction. The laminate 12 has a first ferromagnetic layer 1″, a second ferromagnetic layer 2″, a nonmagnetic layer 3″, and a spin-orbit torque wiring 4″. The first ferromagnetic layer 1″ corresponds to the first ferromagnetic layer 1 except for the curve direction. The second ferromagnetic layer 2″ corresponds to the second ferromagnetic layer 2 except for the curve direction. The nonmagnetic layer 3″ corresponds to the nonmagnetic layer 3 except for the curve direction. The spin-orbit torque wiring 4″ corresponds to the spin-orbit torque wiring 4 except for the curve direction. The first ferromagnetic layer 1″, the nonmagnetic layer 3″, and the second ferromagnetic layer 2″ are curved along the spin-orbit torque wiring 4″.

The first via wiring 22 corresponds to the first via wiring 20 except for the curve direction of a first connection surface 22A. The second via wiring 32 corresponds to the second via wiring 30 except for the curve direction of a second connection surface 32A. An insulating layer 52 corresponds to the insulating layer 50 except for the curve direction of a third connection surface 52A. It is preferable that the sum of the curved surface length of the first connection surface 22A and the second connection surface 32A be longer than the curved surface length of the third connection surface 52A, and it is preferable that the total area of the first connection surface 22A and the second connection surface 32A be larger than the area of the third connection surface 52A.

As shown in FIG. 7, the first connection surface 22A has an inflection point p1 where the positive and negative signs of the inclination change in the XZ cross section. The second connection surface 32A has an inflection point p2 where the positive and negative signs of the inclination change in the XZ cross section.

The magnetoresistance effect element 102 according to the third embodiment differs from the magnetoresistance effect element 100 simply in the curve direction of the layers and exhibits an effect similar to that of the magnetoresistance effect element 100. In addition, since the first connection surface 22A and the second connection surface 32A are curved a plurality of times, the contact areas of the spin-orbit torque wiring 4′ with respect to the first via wiring 22 and the second via wiring 32 can be further increased so that the heat dissipation properties of the magnetoresistance effect element 102 can be further enhanced.

### REFERENCE SIGNS LIST

1, 1′, 1″ First ferromagnetic layer
2, 2′, 2″ Second ferromagnetic layer
3, 3′, 3″ Nonmagnetic layer
4, 4′, 4″ Spin-orbit torque wiring
5, 5′, 5″ Electrode
10, 11, 12 Laminate
20, 21, 22, 25 First via wiring
20A, 21A, 22A First connection surface
30, 31, 32, 35 Second via wiring
30A, 31A, 32A Second connection surface
50, 51, 52, 55 Insulating layer
50A, 51A, 52A Third connection surface
90 Insulating layer
100, 101, 102 Magnetoresistance effect element
200 Magnetic memory
L Reference surface
p1, p2 Inflection point
R Resist

What is claimed is:

1. A magnetoresistance effect element comprising:
a laminate;
a first via wiring; and
a second via wiring,
wherein the laminate has a spin-orbit torque wiring, a first ferromagnetic layer, a nonmagnetic layer, and a second ferromagnetic layer,
the first ferromagnetic layer is located between the spin-orbit torque wiring and the nonmagnetic layer in a lamination direction of the laminate,
the nonmagnetic layer is located between the first ferromagnetic layer and the second ferromagnetic layer in the lamination direction of the laminate,
the first via wiring is connected to the spin-orbit torque wiring,
the second via wiring is connected to the spin-orbit torque wiring at a position different from a position of the first via wiring,
the spin-orbit torque wiring is curved in the lamination direction with respect to a reference surface orthogonal to the lamination direction, and
a first connection surface in contact with the spin-orbit torque wiring of the first via wiring and a second connection surface in contact with the spin-orbit torque wiring of the second via wiring are curved along the spin-orbit torque wiring.

2. The magnetoresistance effect element according to claim 1,
wherein the spin-orbit torque wiring is curved in an upward convex manner with respect to the reference surface.

3. The magnetoresistance effect element according to claim 1,
wherein the spin-orbit torque wiring is curved in a downward convex manner with respect to the reference surface.

4. The magnetoresistance effect element according to claim 1,
wherein when cut along a straight line connecting the first via wiring and the second via wiring at a shortest distance in the lamination direction, the sum of a curved surface length of the first connection surface and a curved surface length of the second connection surface is longer than a curved surface length of a part other than the first connection surface and the second connection surface.

5. The magnetoresistance effect element according to claim 1,
wherein a total area of the first connection surface and the second connection surface in the lamination direction is larger than an area of a part other than the first connection surface and the second connection surface in the laminate.

6. The magnetoresistance effect element according to claim 1,
wherein when cut along a straight line connecting the first via wiring and the second via wiring at a shortest distance in the lamination direction, the first connection surface or the second connection surface has an inflection point where positive and negative signs of an inclination change.

7. The magnetoresistance effect element according to claim 1,
wherein an angle formed by a side surface of the laminate and an interface between the nonmagnetic layer and the second ferromagnetic layer is larger than 90°.

8. The magnetoresistance effect element according to claim 1 further comprising:
an insulating layer,
wherein at least a part of the insulating layer is sandwiched between the first via wiring and the second via wiring, and
a third connection surface in contact with the spin-orbit torque wiring of the insulating layer is curved along the spin-orbit torque wiring.

9. The magnetoresistance effect element according to claim 1,
wherein the first ferromagnetic layer, the nonmagnetic layer, and the second ferromagnetic layer are curved along the spin-orbit torque wiring.

10. A magnetic memory comprising:
the magnetoresistance effect element according to claim 1.
